(19) United States
(12) Patent Application Publication
(10) Pub. No.: US 2025/0266248 A1
(43) Pub. Date: Aug. 21, 2025

(54) ELECTRIC BIAS CONTROL IN PLASMA PROCESSING

(71) Applicant: Tokyo Electron Limited, Tokyo (JP)

(72) Inventors: Chishio KOSHIMIZU, Kurokawa-gun (JP); Yuto KOSAKA, Kurokawa-gun (JP)

(73) Assignee: Tokyo Electron Limited, Tokyo (JP)

(21) Appl. No.: 19/199,575

(22) Filed: May 6, 2025

Related U.S. Application Data
(63) Continuation of application No. PCT/JP2023/039941, filed on Nov. 6, 2023.

(30) Foreign Application Priority Data
Nov. 18, 2022 (JP) 2022-184995

(51) Int. Cl. H01J 37/32

(52) U.S. Cl. CPC H01J 37/32697; H01J 37/32128; H01J 37/32146; H01J 2237/151

(57) ABSTRACT

A plasma processing apparatus discloses herein may include a chamber, substrate support, a radio frequency power supply, and a bias power supply. The substrate support is disposed in the chamber. The radio frequency power supply is configured to supply the source radio frequency power in a first partial period including a rise time of the source radio frequency power and a second partial period subsequent to the first partial period. The bias power supply is configured to supply a pulse of the electric bias to the substrate support in the first partial period, and stop supply of the electric bias from an end time of supply of the pulse of the electric bias to at least a time point between a start time point and an end time point of the second partial period.

### CROSS-REFERENCE TO RELATED APPLICATIONS

This application is a continuation application of PCT Application No. PCT/JP2023/039941, filed on Nov. 6, 2023, which claims the benefit of priority from Japanese Patent Application No. 2022-184995, filed on Nov. 18, 2022. The entire contents of the above listed PCT and priority applications are incorporated herein by reference.

### BACKGROUND

### Field

The present disclosure relates to a plasma processing apparatus and a plasma processing method.

### Description of the Related Art

A plasma processing apparatus is used in plasma processing to be performed on a substrate. The plasma processing apparatus generates plasma from a gas in a chamber by supplying a source radio frequency power. The plasma processing apparatus uses a bias radio frequency power to attract ions from the plasma generated in the chamber into the substrate. Japanese Unexamined Patent PUblication No. 2009-246091 discloses a plasma processing apparatus that modulates a power level and a frequency of a bias radio frequency power.

### SUMMARY

Disclosed herein is a plasma processing apparatus. The plasma processing apparatus may include a chamber; a substrate support disposed in the chamber; a radio frequency power supply electrically coupled to the chamber and configured to generate source radio frequency power to generate plasma in the chamber; and a bias power supply electrically coupled to the substrate support and configured to generate an electric bias to attract ions into the substrate support, wherein the radio frequency power supply is configured to supply the source radio frequency power in a first partial period including a rise time of the source radio frequency power and a second partial period subsequent to the first partial period, and the bias power supply is configured to supply a pulse of the electric bias to the substrate support in the first partial period, and stop supply of the electric bias from an end time of supply of the pulse of the electric bias to at least a time point between a start time point and an end time point of the second partial period.

### BRIEF DESCRIPTION OF THE DRAWINGS

FIG. 1 is a diagram for describing a configuration example of a plasma processing system.

FIG. 2 is a diagram for describing a configuration example of a capacitively coupled plasma processing apparatus.

FIG. 3 is a diagram for describing a configuration example of a capacitively coupled plasma processing apparatus.

FIG. 4A and FIG. 4B are diagrams illustrating examples of waveforms of an electric bias.

FIG. 5 is an example of a timing chart related to a plasma processing apparatus according to one example embodiment.

FIG. 6A to FIG. 6E are diagrams illustrating a temporal change of a source frequency in the plasma processing apparatus according to one example embodiment.

FIG. 7A to FIG. 7E are diagrams illustrating a temporal change of a source frequency in the plasma processing apparatus according to one example embodiment.

FIG. 8A to FIG. 8E are diagrams illustrating a temporal change of a source frequency in the plasma processing apparatus according to one example embodiment.

FIG. 9 is a flowchart of a plasma processing method according to one example embodiment.

FIG. 10 is a timing chart illustrating another example related to a plasma processing apparatus according to one example embodiment.

FIG. 11 is a timing chart of still another example related to the plasma processing apparatus according to one example embodiment.

### DETAILED DESCRIPTION

In the following, various example embodiments will be described in detail with reference to the drawings. In the drawings, the same or equivalent portions are denoted by the same reference symbols.

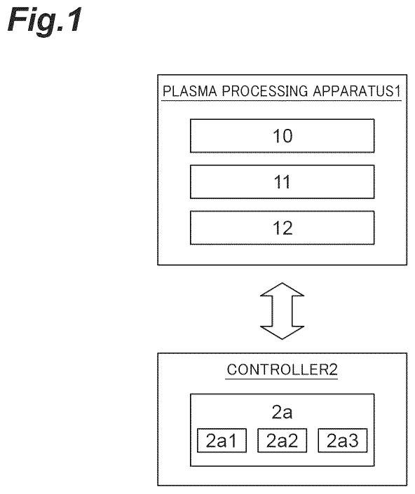

FIG. 1 illustrates an example configuration of a plasma processing system. In one example embodiment, the plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator.

The controller 2 processes computer executable instructions causing the plasma processing apparatus 1 to perform various operations described in this disclosure. The controller 2 may be configured to control individual components of the plasma processing apparatus 1 such that these components execute the various operations. In an example embodiment, the controller 2 may be partially or entirely incorporated into the plasma processing apparatus 1. In an example embodiment, the controller 2 may include a computer 2a. In an example embodiment, the computer 2a may include a processor (CPU: Central Processing Unit) 2al, a storage 2a2, and a communication interface 2a3. The processor 2al may be configured to perform various controlling operations in accordance with a program stored in the storage 2a2. The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

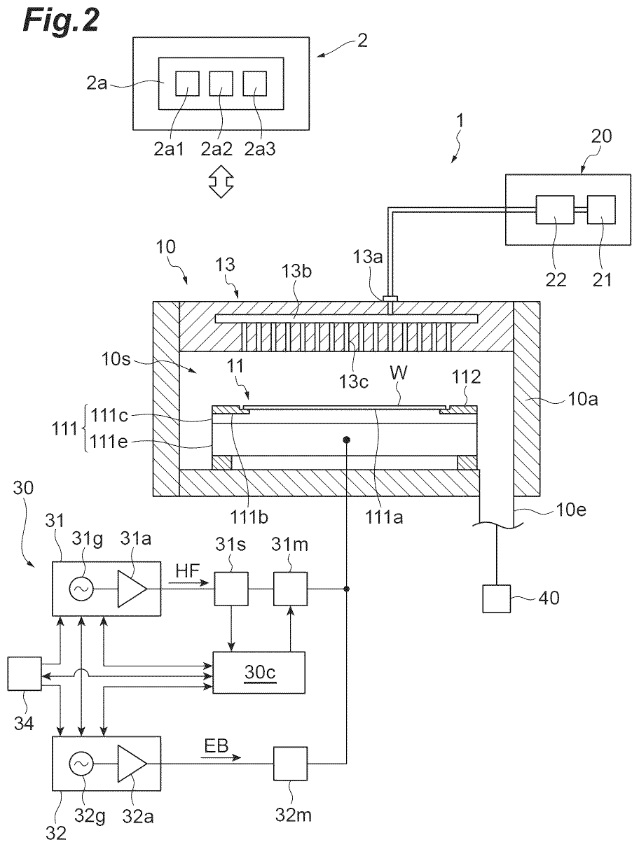

An example configuration of a capacitively coupled plasma processing apparatus, which is an example of the plasma processing apparatus 1, will now be described. FIG. 2 illustrates an example configuration of the capacitively coupled plasma processing apparatus.

The capacitively coupled plasma processing apparatus 1 includes a plasma processing chamber 10, a gas supply 20, a power supply system 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an example embodiment, the showerhead 13 configures at least a part of the ceiling of the plasma processing chamber 10. The plasma processing chamber 10 has a plasma processing space 10s that is defined by the showerhead 13, the sidewall 10a of the plasma processing chamber 10, and the substrate support 11. The sidewall 10a is grounded. The showerhead 13 and the substrate support 11 are electrically insulated from the housing of the plasma processing chamber 10.

The substrate support 11 includes a body 111 and a ring assembly 112. The body 111 has a central region 111a or a substrate supporting surface for supporting a substrate W or wafer and an annular region 111b or a ring supporting surface for supporting the ring assembly 112. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. In an example embodiment, the body 111 includes a base 111 and an electrostatic chuck 111c. The base 111 includes a conductive member. The conductive member of the base 111 can function as a lower electrode. The electrostatic chuck 111c is disposed on the base 111. An upper surface of the electrostatic chuck 111c includes the substrate supporting surface 111a. The ring assembly 112 includes one or more annular members. At least one of the annular members is an edge ring. The substrate support 11 may also include a temperature adjusting module (not shown) that is configured to adjust at least one of the electrostatic chuck 111c, the ring assembly 112, and the substrate W to a target temperature. The temperature adjusting module may be a heater, a heat transfer medium, a flow passage, or any combination thereof. A heat transfer fluid, such as brine or gas, flows into the flow passage. The substrate support 11 may further include a heat transfer gas supply configured to supply a heat transfer gas to a gap between the rear surface of the substrate W and the substrate supporting surface 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes a conductive member. The conductive member of the showerhead 13 functions as an upper electrode. The gas introduction unit may include one or more side gas injectors provided at one or more openings formed in the sidewall 10a, in addition to the showerhead 13.

The gas supply 20 may include one or more gas sources 21 and one or more flow controller s22. In an example embodiment, the gas supply 20 is configured to supply one or more process gases from the respective gas sources 21 through the respective flow controller 22 into the showerhead 13. Each flow controller 22 may include, for example, a mass flow controller or a pressure-controlled flow controller. The gas supply 20 may include one or more flow modulation devices that can modulate or pulse the flow of the one or more process gas.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

The plasma processing apparatus 1 further includes a power supply system 30. The power supply system 30 includes a radio frequency power supply 31 and a controller 30c. The power supply system 30 may further include a bias power supply 32. The power supply system 30 may further include one or more sensors 31s.

The radio frequency power supply 31 is electrically coupled to a chamber (plasma processing chamber 10), and is configured to generate a source radio frequency power HF to generate plasma in the chamber. The source radio frequency power HF has a source frequency fₛ. The source frequency fₛ is, for example, a frequency in a range of 13 MHz or higher and 200 MHz or lower. The source frequency fₛ may be set to 27 MHz, 40.68 MHZ, 60 MHZ, or 100 MHz. A power level of the source radio frequency power HF is, for example, 500 W or higher and 20 kW or lower.

In an example embodiment, the radio frequency power supply 31 may include a radio frequency signal generator 31g and an amplifier 31a. The radio frequency signal generator 31g generates a radio frequency signal. The amplifier 31a generates the source radio frequency power HF by amplifying the radio frequency signal input from the radio frequency signal generator 31g, and outputs the source radio frequency power HF. The radio frequency signal generator 31g may be configured by a programmable logic device, such as a programmable processor or an FPGA. Further, a D/A converter may be connected between the radio frequency signal generator 31g and the amplifier 31a.

The radio frequency power supply 31 is connected to a radio frequency electrode via a matcher 31m. A base 111 constitutes the radio frequency electrode in an example embodiment. In another example embodiment, the radio frequency electrode may be an electrode disposed in an electrostatic chuck 111c. The radio frequency electrode may be an electrode common to a bias electrode described later. Alternatively, the radio frequency electrode may be an upper electrode. The matcher 31m includes a matching circuit. The matching circuit of the matcher 31m has variable impedance. The matching circuit of the matcher 31m is controlled by the controller 30c. The impedance of the matching circuit of the matcher 31m is adjusted to match the impedance on the load side with the output impedance of the radio frequency power supply 31. In one example embodiment, the impedance of the matching circuit of the matcher 31m in a case where the source radio frequency power HF is supplied is set to match the impedance on the load side in a case where the plasma is in a steady state, that is, in a case where the reflection of the source radio frequency power HF is suppressed or converged, with the output impedance of the radio frequency power supply 31 in the second partial period SP₂ described below.

The one or more sensors 31s may be connected between the radio frequency power supply 31 and the matcher 31m. Alternatively, one or more sensors 31s may be connected between the bias electrode and a junction of the electrical path extending from the matcher 31m to the bias electrode and the electrical path extending from the bias power supply 32 or the matcher 32m which will be described later to the bias electrode. Alternatively, the one or more sensors 31s may be connected between the junction and the matcher 31m. The one or more sensors 31s may be sensors separated from the matcher 31m or may be a part of the matcher 31m.

The one or more sensors 31s may include a directional coupler. The directional coupler is configured to detect a power level of a reflected wave of the source radio frequency power HF returned from the load of the radio frequency power supply 31, and notify the controller 30c of the detected power level of the reflected wave.

Further, the one or more sensors 31s may include a VI sensor. The VI sensor is configured to detect a voltage V_{HF} and a current I_{HF} of the source radio frequency power, and determine impedance Z_{L} on the load side of the radio frequency power supply 31 from the voltage V_{HF} and the current I_{HF}. The VI sensor may be configured to determine a phase difference between the voltage V_{HF} and the current I_{HF}.

The bias power supply 32 is electrically coupled to the bias electrode. The base 111e constitutes the bias electrode in an example embodiment. In another example embodiment, the bias electrode may be an electrode provided in the electrostatic chuck 111c. The bias power supply 32 is configured to supply an electric bias EB (or bias energy) to the bias electrode.

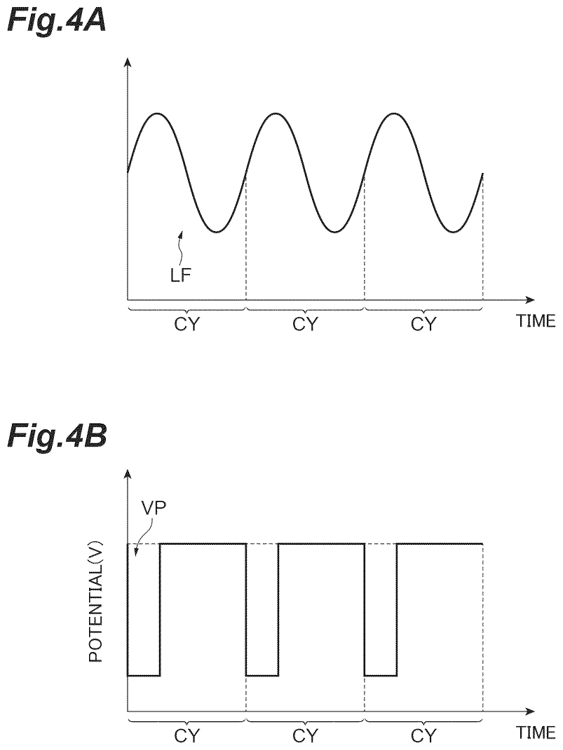

Hereinafter, FIG. 4A and FIG. 4B will be described with reference to FIGS. 1 to 3. Each of FIG. 4A and FIG. 4B is a diagram illustrating an example of a waveform of the electric bias. The bias power supply 32 is configured to periodically supply the electric bias EB having a waveform cycle CY to the bias electrode. That is, the electric bias EB is supplied to the bias electrode in each of a plurality of waveform cycles CY which are repetitions of the waveform cycle CY. The waveform cycle CY is defined by the bias frequency. The bias frequency is, for example, a frequency of 50 kHz or higher and 27 MHz or lower. The time length of the waveform cycle CY is the reciprocal of the bias frequency.

As illustrated in FIG. 4A, the electric bias EB may be bias radio frequency power LF having the bias frequency. That is, the electric bias EB may have a sinusoidal waveform of which a frequency is the bias frequency. In this case, the bias power supply 32 is electrically connected to the bias electrode via the matcher 32m as illustrated in FIG. 2. The variable impedance of the matcher 32m is set to reduce the reflection from the load of the bias radio frequency power LF.

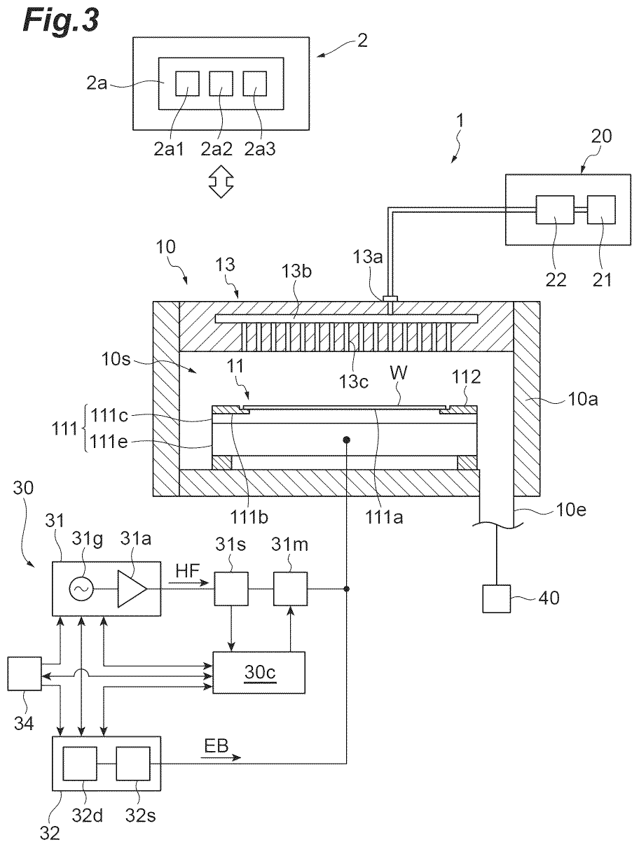

Alternatively, as illustrated in FIG. 4B, the electric bias EB may include a voltage pulse VP. The voltage pulse VP is applied to the bias electrode in the waveform cycle CY. The voltage pulse VP is periodically applied to the bias electrode at a time interval of the same length as the time length of the waveform cycle CY. The waveform of the voltage pulse VP may be a rectangular wave, a triangular wave, or any waveform. Polarity of the voltage of the voltage pulse VP is set to cause a potential difference between a substrate W and the plasma to allow the ions from the plasma to be attracted into the substrate W. The voltage pulse VP may be a negative voltage pulse or a negative direct current voltage pulse. In a case where the electric bias EB is the voltage pulse VP, the plasma processing apparatus 1 does not include the matcher 32m as illustrated in FIG. 3.

As illustrated in FIG. 2, the bias power supply 32 may include a signal generator 32g and an amplifier 32a. The signal generator 32g generates a signal from which the electric bias EB is to be generated. The amplifier 32a generates the electric bias EB by amplifying the signal input from the signal generator 32g, to supply the generated electric bias EB to the bias electrode. The signal generator 32g may be configured by a programmable logic device, such as a programmable processor or an FPGA. Further, a D/A converter may be connected between the signal generator 32g and the amplifier 32a.

In a case where the electric bias EB includes the voltage pulse VP, the bias power supply 32 may include a direct current power supply 32d and a switch 32s as illustrated in FIG. 3. In this case, the bias power supply 32 generates the voltage pulse VP by switching between the output and the output stop of the direct current voltage from the direct current power supply 32d by opening and closing the switch 32s.

The bias power supply 32 is synchronized with the radio frequency power supply 31. A synchronization signal used for this purpose may be supplied from the bias power supply 32 to the radio frequency power supply 31. Alternatively, the synchronization signal may be supplied from the radio frequency power supply 31 to the bias power supply 32. Alternatively, the synchronization signal may be supplied to the radio frequency power supply 31 and the bias power supply 32 from another device, such as the controller 30c.

In one example embodiment, the radio frequency power supply 31 may be configured to supply a pulse of the source radio frequency power HF to the radio frequency electrode. The pulses of the source radio frequency power HF may be periodically supplied. In addition, the bias power supply 32 may be configured to supply the pulse of the electric bias EB to the bias electrode. The pulses of the electric bias EB may be periodically supplied. In this case, each of the radio frequency power supply 31 and the bias power supply 32 may identify the supply period of the pulse by the signal provided from the pulse controller 34. The controller 2 may function as the pulse controller 34. The pulse controller 34 may be a part of the radio frequency power supply 31.

The controller 30c is configured to control the radio frequency power supply 31. The controller 30c may further control the bias power supply 32. The controller 30c may be configured by a processor, such as a CPU. The controller 30c may be a part of the matcher 31m, may be a part of the radio frequency power supply 31, or may be a controller separated from the matcher 31m and the radio frequency power supply 31. Alternatively, the controller 2 may also serve as the controller 30c. The controller 30c may also serve as the pulse controller 34.

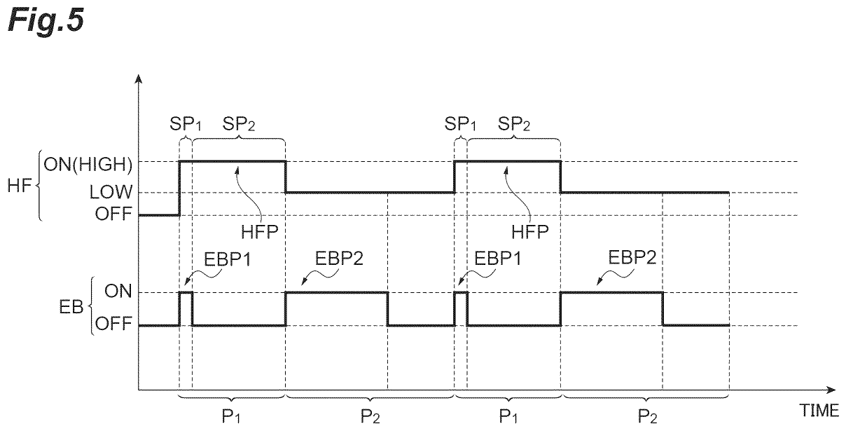

The description will be made below with reference to FIG. 5. FIG. 5 is an example of a timing chart related to a plasma processing apparatus according to one example embodiment. FIG. 5 shows timing charts of the source radio frequency power HF and the electric bias EB. In FIG. 5, “ON” of the source radio frequency power HF indicates that the source radio frequency power HF is supplied, and “OFF” of the source radio frequency power HF indicates that the supply of the source radio frequency power HF is stopped. In FIG. 5, “LOW” of the source radio frequency power HF indicates that the power level of the source radio frequency power HF is lower than the power level of the source radio frequency power HF indicated by “HIGH”. In FIG. 5, “ON” of the electric bias EB indicates that the electric bias EB is supplied, and “OFF” of the electric bias EB indicates that the supply of the electric bias EB is stopped.

As illustrated in FIG. 5, the radio frequency power supply 31 is configured to supply the source radio frequency power HF in a first partial period SP₁ and a second partial period SP₂. The first partial period SP₁ is a period including the rise time of the source radio frequency power HF. The rise time of the source radio frequency power HF is the start time of the supply of the source radio frequency power HF or the start time of the supply of the pulse HFP of the source radio frequency power HF, which will be described later. The second partial period SP₂ is a period subsequent to the first partial period SP₁. The length of the first partial period SP₁ is shorter than the length of the second partial period SP₂. The length of the first partial period SP₁ is the same as or longer than the time length of the waveform cycle CY. The length of the first partial period SP₁ may be 10 us or less.

In one example embodiment, as illustrated in FIG. 5, the radio frequency power supply 31 may supply the source radio frequency power HF (that is, the pulse HFP) in the first period P₁. The first period P₁ is a period including a first partial period SP₁ and a second partial period SP₂. In addition, the radio frequency power supply 31 may stop the supply of the source radio frequency power HF in the second period P₂ alternating with the first period P₁. Alternatively, the radio frequency power supply 31 may set the power level of the source radio frequency power HF in the second period P₂ to a level lower than the power level of the source radio frequency power HF (pulse HFP) in the first period P₁. As described above, the radio frequency power supply 31 may periodically supply the pulse HFP of the source radio frequency power HF.

In another example embodiment, the radio frequency power supply 31 may continuously supply the source radio frequency power HF. That is, the radio frequency power supply 31 may continuously supply the source radio frequency power HF in a single period including the first partial period SP₁ and the second partial period SP₂.

The bias power supply 32 supplies the pulse EBP1 of the electric bias EB to the substrate support 11 (that is, the bias electrode) in the first partial period SP₁. As illustrated in FIG. 5, the bias power supply 32 may start the supply of the pulse EBP1 to the substrate support 11 at the same time as the start time point of the first partial period SP₁. The time length of the period in which the pulse EBP1 is supplied in the first partial period SP₁ may be the same as the length of the single waveform cycle CY. That is, in the first partial period SP₁, the electric bias EB of only one cycle (single waveform cycle CY) may be supplied.

The bias power supply 32 stops the supply of the electric bias EB from the end time of the supply of the pulse EBP1 to at least a time point between the start time point and the end time point of the second partial period SP₂. In one example embodiment, the bias power supply 32 may stop the supply of the electric bias EB in the second partial period SP₂. Alternatively, the bias power supply 32 may stop the supply of the electric bias EB from the end time of the supply of the pulse EBP1 to a time point between the start time point and the end time point of the second partial period SP₂.

The pulse EBP1 has a level at which an absolute value of the self-bias voltage Vdc of the substrate support 11 (that is, the bias electrode) in a case where the pulse EBP1 is supplied is equal to or higher than an absolute value of the self-bias voltage Vdc of the substrate support 11 (that is, the bias electrode) in a period in which the plasma is in a steady state within the second partial period SP₂. The level of the pulse EBP1 is set in advance. The level of the pulse EBP1 is a power level of the bias radio frequency power LF in a case where the electric bias EB is the bias radio frequency power LF. In a case where the electric bias EB is the voltage pulse VP, the level of the pulse EBP1 is an absolute value of a difference between a voltage level of the voltage pulse VP and a reference level. In a case where the electric bias EB is the voltage pulse VP, the level of the pulse EBP1 is higher as the voltage level of the voltage pulse VP is farther from the reference level on the negative side.

In one example embodiment, the bias power supply 32 may supply the pulse EBP2 of the electric bias EB to the substrate support 11 (that is, the bias electrode) in the second period P₂. That is, the bias power supply 32 may periodically supply the pulse EBP2. In a period in which the pulse EBP2 is supplied, the waveform cycle CY is repeated. The supply of the pulse EBP2 may be started at the start time point of the second period P₂ or after the start time point. Alternatively, the supply of the pulse EBP2 may start from a time point between the start time point and the end time point of the second partial period SP₂.

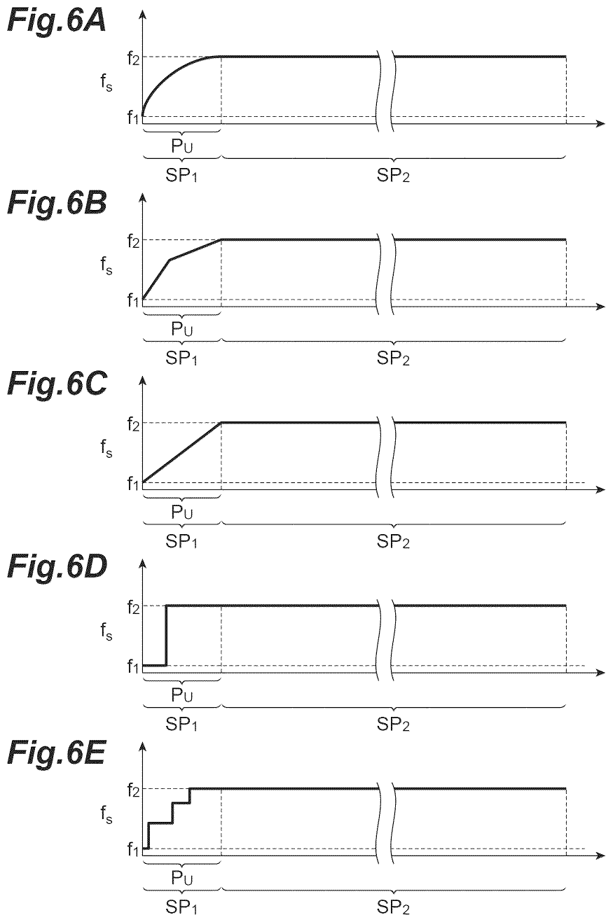

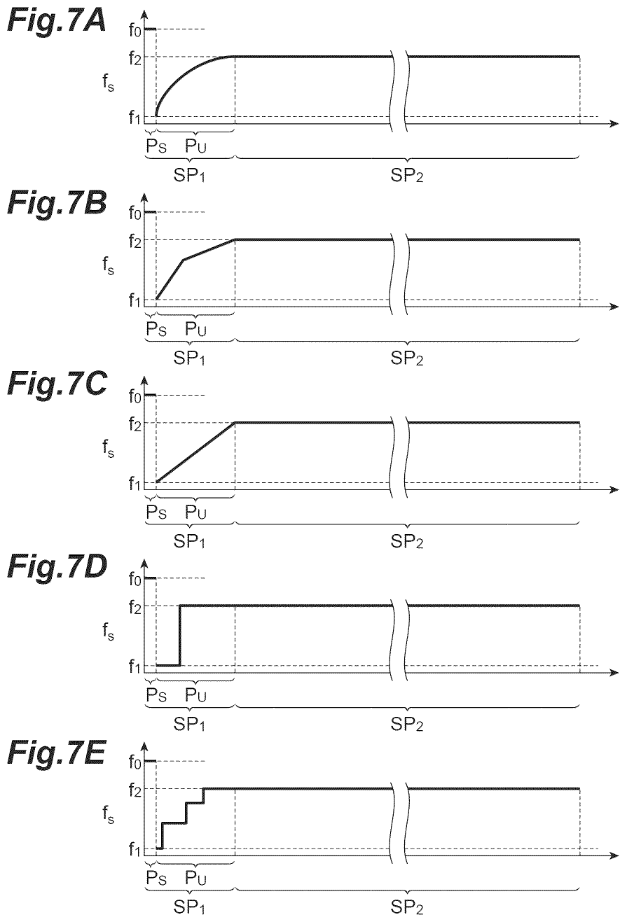

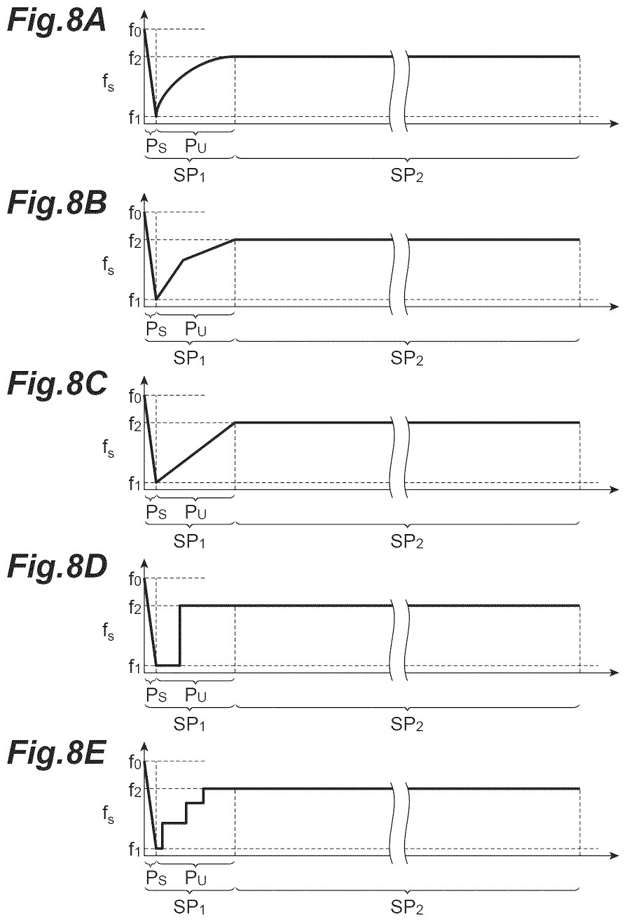

In one example embodiment, the radio frequency power supply 31 may fix the source frequency of the source radio frequency power HF from the start to the stop of the supply of the source radio frequency power HF. Alternatively, as illustrated in FIG. 6A to FIG. 6E, FIG. 7A to FIG. 7E, FIG. 8A to FIG. 8E, the radio frequency power supply 31 may change the source frequency fₛ of the source radio frequency power HF in the first partial period SP₁. Each of FIG. 6A to FIG. 6E, FIG. 7A to FIG. 7E, FIG. 8A to FIG. 8E is a diagram illustrating a temporal change of a source frequency in the plasma processing apparatus according to one example embodiment.

Specifically, as illustrated in FIG. 6A to FIG. 6E, FIG. 7A to FIG. 7E, FIG. 8A to FIG. 8E, the radio frequency power supply 31 may set the time series of the source frequency fₛ to the time series of the frequency that increases gradually or stepwise from a first frequency f₁ to a second frequency f₂ in the frequency increase period P_{U} in the first partial period SP₁. The radio frequency power supply 31 may gradually or stepwise increase the source frequency fₛ from the first frequency f₁ to the second frequency f₂ without decreasing the source frequency fₛ in the frequency increase period P_{U}. The radio frequency power supply 31 may obtain the time series of the source frequency fₛ used in the frequency increase period P_{U} by interpolation using one or more straight lines or curves with respect to the first frequency f₁ and the second frequency f₂.

As illustrated in FIG. 6A to FIG. 6E, the frequency increase period P_{U} may be the same as the first partial period SP₁. That is, the start time point of the first partial period SP₁ and the start time point of the frequency increase period P_{U} may be the same, and the end time point of the first partial period SP₁ and the end time point of the frequency increase period P_{U} may be the same. In this case, the source frequency fₛ is set to the first frequency f₁ at the start time point of the first partial period SP₁ and increases to the second frequency f₂ in the first partial period SP₁.

As illustrated in FIG. 7A to FIG. 7E and FIG. 8A to FIG. 8E, the first partial period SP₁ may include a start period Pₛ before the frequency increase period P_{U}. The start period Pₛ may include a start time point of the first partial period SP₁. As illustrated in FIG. 7A to FIG. 7E, the source frequency fₛ may be maintained at the frequency f₀ in the start period Pₛ. As illustrated in FIG. 8A to FIG. 8E, the source frequency fₛ may be decreased from the frequency f₀ to the first frequency f₁ in the start period Pₛ. The frequency f₀ may be larger than the second frequency f₂. The frequency f₀ may be a resonance frequency of the source radio frequency power HF with respect to the chamber 10 in a case where plasma is not generated in the chamber 10. In this case, discharge is likely to occur in the start period Pₛ. In addition, only the first partial period SP₁ in the initial first period P₁ among the first periods P₁ that are repetitions of the first period P₁ may include the start period Pₛ, and the other first periods P₁ may include only the frequency increase period P_{U}.

In the example illustrated in each of FIG. 6A, FIG. 7A, and FIG. 8A, the time series of the source frequency fₛ in the frequency increase period P_{U} is set by interpolation using one curve with respect to the first frequency f₁ and the second frequency f₂. In the example illustrated in each of FIG. 6B, FIG. 7B, and FIG. 8B, the time series of the source frequency fₛ in the frequency increase period P_{U} is set by interpolation using two straight lines with respect to the first frequency f₁, the second frequency f₂, and the intermediate frequency between the first frequency f₁ and the second frequency f₂. In the example illustrated in each of FIG. 6C, FIG. 7C, and FIG. 8C, the time series of the source frequency fₛ in the frequency increase period P_{U} is set by interpolation using one straight line with respect to the first frequency f₁ and the second frequency f₂. In the example illustrated in each of FIG. 6D, FIG. 6E, FIG. 7D, FIG. 7E, FIG. 8D, and FIG. 8E, the time series of the source frequency fₛ in the frequency increase period P_{U} is set to the time series of the frequency that stepwise increases from the first frequency f₁ to the second frequency f₂.

The time series of the source frequency fₛ used in the first partial period SP₁ of each of the plurality of first periods P₁, which are the repetition of the first period P₁, may be the same as the time series of the source frequency fₛ used in the first partial period SP₁ of each of all the other first periods P₁. That is, in the embodiment in which the pulse HFP of the source radio frequency power HF is periodically supplied, the same time series of the source frequency fₛ may be used in each of the first partial periods SP₁ of the plurality of first periods P₁. Alternatively, the time series of the source frequency fₛ used in the first partial period SP₁ in each of all the first periods excluding the initial first period among the plurality of first periods P₁ may be the same as the time series fₛ of the source frequency used in the first partial period SP₁ in each of the other first periods among all the first periods excluding the initial first period. That is, the same time series of the source frequency fₛ may be used in the first partial period SP₁ of each of all the first periods P₁ excluding the initial first period among the plurality of first periods P₁. Alternatively, the time series of the source frequency fₛ used in the first partial period SP₁ of each of the plurality of first periods P₁ may be changed by inter pulse feedback which will be described later.

In a case where the source frequency fₛ is changed in the first partial period SP₁, the radio frequency power supply 31 may fix the source frequency fₛ at least for a predetermined period from the start of the second partial period SP₂. The radio frequency power supply 31 may fix the source frequency fₛ to the second frequency f₂ at least for a predetermined period from the start of the second partial period SP₂. The radio frequency power supply 31 may fix the source frequency fₛ over the entire second partial period SP₂. The radio frequency power supply 31 may fix the source frequency fₛ in the second partial period SP₂ to the second frequency f₂.

Hereinafter, the inter pulse feedback will be described. In the following description, the first partial period SP₁[n] represents the first partial period SP₁ in the n-th first period P₁ in the repetition of the first period P₁, that is, the repetition of the plurality of first periods P₁. In addition, am represents a time point after a lapse of m time from the start time point of the first partial period SP₁. In addition, the source frequency fₛ[SP₁[n], am] represents the source frequency fₛ used at the time point am of the first partial period SP₁[n].

In the inter pulse feedback, the degree of reflection of the source radio frequency power is used. The degree of reflection may be acquired as a power level of a reflected wave of the source radio frequency power HF. The degree of reflection may be acquired as a value of a ratio of the power level of the reflected wave of the source radio frequency power HF to a power level of a traveling wave of the source radio frequency power HF or a set output power level of the source radio frequency power HF. Alternatively, the degree of reflection may be acquired as a deviation amount of the impedance Z_{L} with respect to characteristic impedance (for example, 50Ω) of a power feed line to the radio frequency electrode of the source radio frequency power HF.

Alternatively, the degree of reflection may be acquired as the phase difference between the voltage V_{HF} and the current I_{HF}. Alternatively, the degree of reflection may be acquired as another quantity representing a degree of matching with the plasma at the source frequency fₛ. In any case, the degree of reflection may be acquired by the one or more sensors 31s or may be determined from measured values acquired by one or more sensors 31s.

In the inter pulse feedback, the controller 30c sets the source frequency fₛ[SP₁[n], αₘ] to suppress the degree of reflection of the source radio frequency power HF at the time point αₘ in the first partial period SP₁[n] in accordance with a change from the source frequency fₛ[SP₁[n-q], αₘ] at the same time point αₘ in the first partial period SP₁[n-q] to fₛ[SP₁[n-p], am] at the same time point αₘ in the first partial period SP₁[n-p] and a change from the degree of reflection of the source radio frequency power HF at the same time point αₘ in the first partial period SP₁[n-q] to the degree of reflection of the source radio frequency power HF at the time point αₘ in the first partial period SP₁[n-p]. Here, q and p are integers which are 1 or higher, and q is higher than p. For example, q is 2, and p is 1.

In an example, in a case where a change from the degree of reflection of the source radio frequency power HF at the time point αₘ in the first partial period SP₁[n-q] to the degree of reflection of the source radio frequency power HF at the time point αₘ in the first partial period SP₁[n-p] is a decrease in the degree of reflection, the controller 30c sets the source frequency fₛ[SP₁[n], am] to a frequency which is obtained by providing a shift in the same direction as a direction of a change from the source frequency fₛ[SP₁[n-q], am] to the source frequency fₛ[SP₁[n-p], am] to the source frequency fₛ[SP₁[n-p], am]. In a case where a change from the degree of reflection of the source radio frequency power HF at the time point αₘ in the first partial period SP₁[n-q] to the degree of reflection of the source radio frequency power HF at the time point αₘ in the first partial period SP₁[n-p] is an increase in the degree of reflection, the controller 30c sets the source frequency fₛ[SP₁[n], am] to a frequency which is obtained by providing a shift in the reverse direction as the direction of the change from the source frequency fₛ[SP₁[n-q], am] to the source frequency fₛ[SP₁[n-p], am] to the source frequency fₛ[SP₁[n-p], am].

As described above, in the plasma processing apparatus 1, the pulse EBP1 of the electric bias EB is supplied in the first partial period SP₁. As a result, the thickness of the plasma sheath is instantaneously changed to match the impedance on the load side with the output impedance of the radio frequency power supply 31. As a result, the coupling efficiency of the source radio frequency power HF to the plasma is increased within the first partial period SP₁, and the time until the plasma grows and reaches a steady state is shortened. Therefore, according to the plasma processing apparatus 1, it is possible to shorten the time from the rise time of the source radio frequency power HF to the time at which the reflection of the source radio frequency power HF is reduced or converged.

In addition, as described above, the source frequency fₛ may gradually or stepwise increase in the first partial period SP₁. That is, in the first partial period SP₁, the source frequency fₛ is initially low. The coupling efficiency of the source radio frequency power HF having a low source frequency fₛ to the plasma is high in a state where the thickness of the plasma sheath is small. Therefore, in this case, it is possible to further shorten the time from the rise time of the source radio frequency power HF to the time at which the reflection of the source radio frequency power HF is reduced or converged.

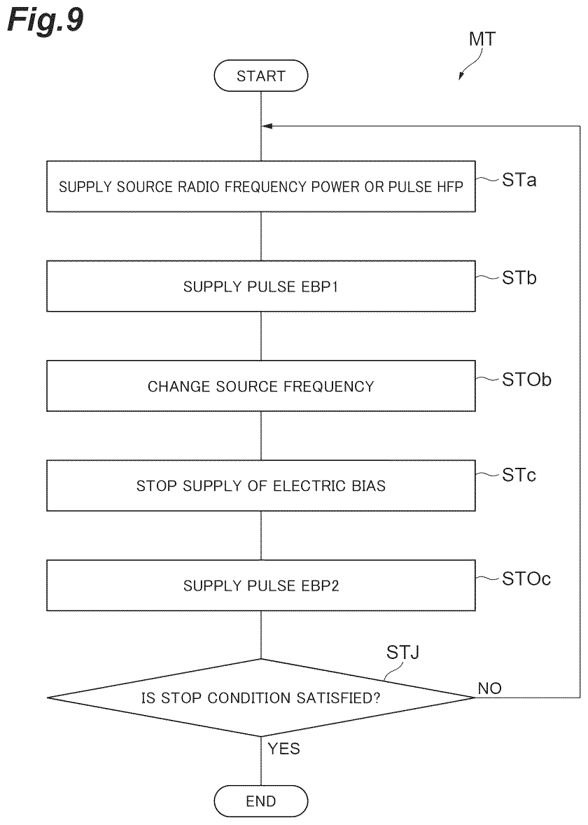

Hereinafter, a plasma processing method according to one example embodiment will be described with reference to FIG. 9. FIG. 9 is a flowchart of the plasma processing method according to one example embodiment. The plasma processing method illustrated in FIG. 9 (hereinafter, referred to as a “method MT”) may be performed in a state where a substrate is placed on the substrate support 11. In order to perform each operation of the method MT, each unit of the plasma processing apparatus 1 may be controlled by the controller 2.

The method MT starts in operation STa. In operation STa, the source radio frequency power HF or the pulse HFP is supplied to generate plasma from gas in the chamber 10. As described above, the source radio frequency power HF or the pulse HFP of the source radio frequency power HF is supplied in the first partial period SP₁ and the second partial period SP₂. The gas is supplied into the chamber from the gas supply 20. In addition, the pressure in the chamber 10 is adjusted by the exhaust system 40.

Operation STb is performed in the first partial period SP₁. In operation STb, as described above, the pulse EBP1 of the electric bias EB is supplied to the bias electrode.

In one example embodiment, operation STOb may be performed in the first partial period SP₁. In operation STOb, as described above, the time series of the source frequency fₛ is set to the time series of the frequency that increases gradually or stepwise from the first frequency f₁ to the second frequency f₂.

Then, operation STc is performed. Operation STc is started immediately after the supply of the pulse EBP1. In operation STc, the supply of the electric bias EB is stopped. The stop of the supply of the electric bias EB is started immediately after the supply of the pulse EBP1 and is continued until at least a time point between the start time point and the end time point of the second partial period SP₂, as described above. The stop of the supply of the electric bias EB may continue until the end time point of the second partial period SP₂.

In one example embodiment, as described above, the first period P₁ and the second period P₂ are alternately repeated. In this case, the method MT includes operation STJ. In operation STJ, it is determined whether or not a stop condition is satisfied. The stop condition is satisfied in a case where the number of times of alternate repetition of the first period P₁ and the second period P₂ reaches a predetermined number of times. In a case where the stop condition is not satisfied, the processing from operation STa is performed again. On the other hand, in a case where the stop condition is satisfied, the method MT is terminated.

While various exemplary embodiments have been described above, various additions, omissions, substitutions and changes may be made without being limited to the example embodiments described above. Elements of the different embodiments may be combined to form another embodiment.

In another example embodiment, the plasma processing apparatus may be an inductively coupled plasma processing apparatus, an ECR plasma processing apparatus, a helical wave excitation plasma processing apparatus, or a surface wave plasma processing apparatus. In any plasma processing apparatus, source radio frequency power HF is used for generating plasma.

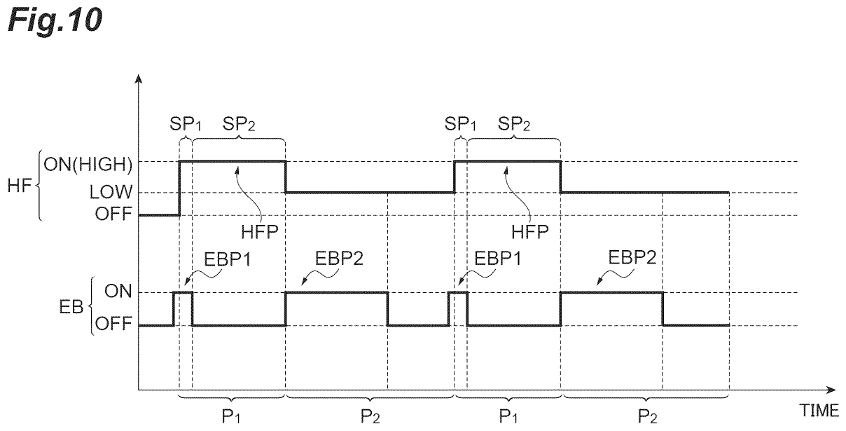

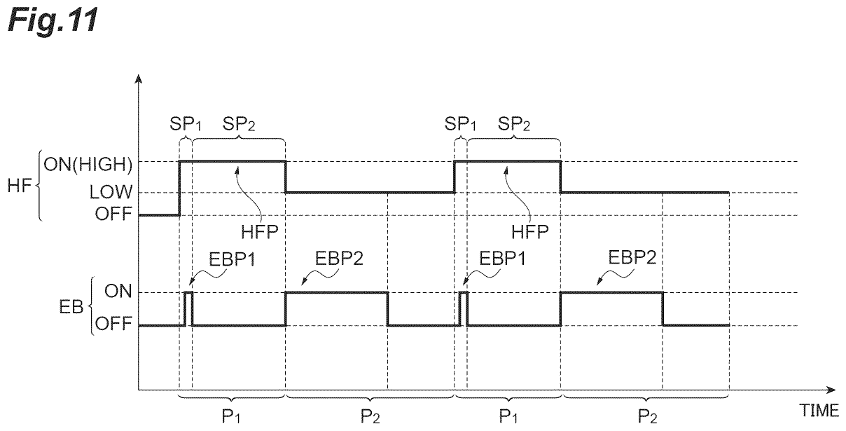

In addition, as illustrated in FIG. 10, the bias power supply 32 may start the supply of the pulse EBP1 to the substrate support 11 before the start time point of the first partial period SP₁. Alternatively, as illustrated in FIG. 11, the bias power supply 32 may start the supply of the pulse EBP1 to the substrate support 11 after the start time point of the first partial period SP₁ in the first partial period SP₁.

The following [E1] to [E17] describes various example embodiments included in the present disclosure.

### [E1]

A plasma processing apparatus including:
a chamber;
a substrate support disposed in the chamber;
a radio frequency power supply electrically coupled to the chamber and configured to generate source radio frequency power to generate plasma in the chamber; and
a bias power supply electrically coupled to the substrate support and configured to generate an electric bias to attract ions into the substrate support,
wherein the radio frequency power supply is configured to supply the source radio frequency power in a first partial period including a rise time of the source radio frequency power and a second partial period subsequent to the first partial period, and
the bias power supply is configured to
   supply a pulse of the electric bias to the substrate support in the first partial period, and
   stop supply of the electric bias from an end time of supply of the pulse of the electric bias to at least a time point between a start time point and an end time point of the second partial period.

### [E2]

The plasma processing apparatus according to E1, wherein the pulse of the electric bias has a level at which an absolute value of a self-bias voltage of the substrate support in a case where the pulse is supplied is equal to or greater than an absolute value of a self-bias voltage of the substrate support in a period in which the plasma is in a steady state within the second partial period.

### [E3]

The plasma processing apparatus according to E1 or E2, wherein the electric bias is bias radio frequency power having a waveform cycle or a pulse of a voltage having a waveform cycle and generated periodically.

### [E4]

The plasma processing apparatus according to any one of E1 to E3, wherein a length of the first partial period is equal to or less than 10 μs.

### [E5]

The plasma processing apparatus according to E3, wherein a time length of a period in which the pulse of the electric bias is supplied in the first partial period is the same as a length of the waveform cycle.

### [E6]

The plasma processing apparatus according to any one of E1 to E5, wherein
the radio frequency power supply is configured to periodically supply a pulse of the source radio frequency power by
   supplying the source radio frequency power in a first period including the first partial period and the second partial period, and
   stopping supply of the source radio frequency power in a second period alternating with the first period or setting a power level of the source radio frequency power to be lower than a power level of the source radio frequency power in the first period, and
the bias power supply is configured to periodically supply another pulse of the electric bias by supplying the electric bias to the substrate support in the second period.

### [E7]

The plasma processing apparatus according to any one of E1 to E6, wherein the radio frequency power supply is configured to fix a source frequency of the source radio frequency power from a start to a stop of the supply of the source radio frequency power.

### [E8]

The plasma processing apparatus according to any one of E1 to E5, wherein the radio frequency power supply is configured to set a time series of a source frequency of the source radio frequency power in the first partial period to a time series of a frequency that increases gradually or stepwise from a first frequency to a second frequency higher than the first frequency.

### [E9]

The plasma processing apparatus according to E8, wherein the source frequency is fixed to the second frequency in the second partial period.

### [E10]

The plasma processing apparatus according to E8 or E9, wherein
the radio frequency power supply is configured to periodically supply a pulse of the source radio frequency power by
   supplying the source radio frequency power in a first period including the first partial period and the second partial period, and
   stopping supply of the source radio frequency power in a second period alternating with the first period or setting a power level of the source radio frequency power to be lower than a power level of the source radio frequency power in the first period, and
the bias power supply is configured to periodically supply another pulse of the electric bias by supplying the electric bias to the substrate support in the second period.

### [E11]

The plasma processing apparatus according to E10, wherein the time series of the source frequency used in the first partial period in each of a plurality of the first periods that are repetitions of the first period is the same as the time series of the source frequency used in the first partial period in each of all other first periods among the plurality of the first periods.

### [E12]

The plasma processing apparatus according to claim 10, wherein the time series of the source frequency used in the first partial period in each of all first periods excluding an initial first period among a plurality of the first periods that are repetitions of the first period is the same as the time series of the source frequency used in the first partial period in each of the other first periods among all the first periods excluding the initial first period.

### [E13]

The plasma processing apparatus according to any one of E8 to E11, wherein the radio frequency power supply is configured to obtain the time series of the source frequency used in the first partial period by interpolation using one or more straight lines or curves with respect to the first frequency and the second frequency.

### [E14]

The plasma processing apparatus according to any one of E1 to E13, wherein the bias power supply is configured to start the supply of the pulse of the electric bias to the substrate support at the same time as a start time point of the first partial period.

### [E15]

The plasma processing apparatus according to any one of E1 to E13, wherein the bias power supply is configured to start the supply of the pulse of the electric bias to the substrate support before a start time point of the first partial period.

### [E16]

The plasma processing apparatus according to E1 to E13, wherein the bias power supply is configured to start the supply of the pulse of the electric bias to the substrate support in the first partial period and after a start time point of the first partial period.

### [E17]

A plasma processing method including:
(a) supplying source radio frequency power from a radio frequency power supply to generate plasma in a chamber of a plasma processing apparatus, the source radio frequency power being supplied in a first partial period including a rise time of the source radio frequency power and a second partial period subsequent to the first partial period;
(b) supplying a pulse of an electric bias to a substrate support provided in the chamber from a bias power supply in the first partial period; and
(c) stopping supply of the electric bias from an end time of the supply of the pulse of the electric bias in the (b) to at least a time point between a start time point and an end time point of the second partial period.

From the foregoing description, it will be appreciated that various example embodiments of the present disclosure have been described herein for purposes of illustration, and that various modifications may be made without departing from the scope and spirit of the present disclosure. Accordingly, the various example embodiments disclosed herein are not intended to be limiting, with the true scope and spirit being indicated by the following claims.

What is claimed is:

1. A plasma processing apparatus comprising:
a chamber;
a substrate support disposed in the chamber;
a radio frequency power supply electrically coupled to the chamber and configured to generate source radio frequency power to generate plasma in the chamber; and
a bias power supply electrically coupled to the substrate support and configured to generate an electric bias to attract ions into the substrate support,
wherein the radio frequency power supply is configured to supply the source radio frequency power in a first partial period including a rise time of the source radio frequency power and a second partial period subsequent to the first partial period, and
the bias power supply is configured to
supply a pulse of the electric bias to the substrate support in the first partial period, and
stop supply of the electric bias from an end time of supply of the pulse of the electric bias to at least a time point between a start time point and an end time point of the second partial period.

2. The plasma processing apparatus according to claim 1,
wherein the pulse of the electric bias has a level at which an absolute value of a self-bias voltage of the substrate support in a case where the pulse is supplied is equal to or greater than an absolute value of a self-bias voltage of the substrate support in a period in which the plasma is in a steady state within the second partial period.

3. The plasma processing apparatus according to claim 1, wherein the electric bias is bias radio frequency power having a waveform cycle or a pulse of a voltage having a waveform cycle and generated periodically.

4. The plasma processing apparatus according to claim 1, wherein a length of the first partial period is equal to or less than 10 μs.

5. The plasma processing apparatus according to claim 3, wherein a time length of a period in which the pulse of the electric bias is supplied in the first partial period is the same as a length of the waveform cycle.

6. The plasma processing apparatus according to claim 1, wherein
the radio frequency power supply is configured to periodically supply a pulse of the source radio frequency power by
supplying the source radio frequency power in a first period including the first partial period and the second partial period, and
stopping supply of the source radio frequency power in a second period alternating with the first period or setting a power level of the source radio frequency power to be lower than a power level of the source radio frequency power in the first period, and
the bias power supply is configured to periodically supply another pulse of the electric bias by supplying the electric bias to the substrate support in the second period.

7. The plasma processing apparatus according to claim 1, wherein the radio frequency power supply is configured to fix a source frequency of the source radio frequency power from a start to a stop of the supply of the source radio frequency power.

8. The plasma processing apparatus according to claim 1, wherein the radio frequency power supply is configured to set a time series of a source frequency of the source radio frequency power in the first partial period to a time series of a frequency that increases gradually or stepwise from a first frequency to a second frequency higher than the first frequency.

9. The plasma processing apparatus according to claim 8, wherein the source frequency is fixed to the second frequency in the second partial period.

10. The plasma processing apparatus according to claim 8, wherein
the radio frequency power supply is configured to periodically supply a pulse of the source radio frequency power by
supplying the source radio frequency power in a first period including the first partial period and the second partial period, and
stopping supply of the source radio frequency power in a second period alternating with the first period or setting a power level of the source radio frequency power to be lower than a power level of the source radio frequency power in the first period, and
the bias power supply is configured to periodically supply another pulse of the electric bias by supplying the electric bias to the substrate support in the second period.

11. The plasma processing apparatus according to claim 10, wherein the time series of the source frequency used in the first partial period in each of a plurality of the first periods that are repetitions of the first period is the same as the time series of the source frequency used in the first partial period in each of all other first periods among the plurality of the first periods.

12. The plasma processing apparatus according to claim 10, wherein the time series of the source frequency used in the first partial period in each of all first periods excluding an initial first period among a plurality of the first periods that are repetitions of the first period is the same as the time series of the source frequency used in the first partial period in each of the other first periods among all the first periods excluding the initial first period.

13. The plasma processing apparatus according to claim 8, wherein the radio frequency power supply is configured to obtain the time series of the source frequency used in the first partial period by interpolation using one or more straight lines or curves with respect to the first frequency and the second frequency.

14. The plasma processing apparatus according to claim 1, wherein the bias power supply is configured to start the supply of the pulse of the electric bias to the substrate support at the same time as a start time point of the first partial period.

15. The plasma processing apparatus according to claim 1, wherein the bias power supply is configured to start the supply of the pulse of the electric bias to the substrate support before a start time point of the first partial period.

16. The plasma processing apparatus according to claim 1, wherein the bias power supply is configured to start the supply of the pulse of the electric bias to the substrate support in the first partial period and after a start time point of the first partial period.

17. A plasma processing method comprising:
(a) supplying source radio frequency power from a radio frequency power supply to generate plasma in a chamber of a plasma processing apparatus, the source radio frequency power being supplied in a first partial period including a rise time of the source radio frequency power and a second partial period subsequent to the first partial period;
(b) supplying a pulse of an electric bias to a substrate support provided in the chamber from a bias power supply in the first partial period; and
(c) stopping supply of the electric bias from an end time of the supply of the pulse of the electric bias in the (b) to at least a time point between a start time point and an end time point of the second partial period.
